(19) United States
(12) Patent Application Publication
(10) Pub. No.: US 2013/0341706 A1
(43) Pub. Date: Dec. 26, 2013

(54) SEMICONDUCTOR MEMORY DEVICE AND MANUFACTURING METHOD OF THE SAME

(71) Applicant: KABUSHIKI KAISHA TOSHIBA, Tokyo (JP)

(72) Inventor: Kouji MATSUO, Aichi (JP)

(73) Assignee: Kabushiki Kaisha Toshiba, Tokyo (JP)

(21) Appl. No.: 13/778,794

(22) Filed: Feb. 27, 2013

(30) Foreign Application Priority Data
Jun. 25, 2012 (JP) 2012-142526

(51) Int. Cl. H01L 29/786; H01L 29/66

(52) U.S. Cl. CPC H01L 29/78642; H01L 29/66666
USPC 257/329; 438/156

(57) ABSTRACT

According to one embodiment, a semiconductor memory device includes a semiconductor laminated film comprising an embedded insulating film, and an SOI layer laminated on a semiconductor substrate. On the embedded insulating film, multiple pillar-shaped gate electrodes embedded in the SOI layer are provided. On the SOI layer, a pillar-shaped gate insulating film is provided to surround the side surface of each of the pillar-shaped gate electrodes. On the SOI layer, multiple first bit lines are arranged. On the pillar-shaped gate electrodes, multiple word lines are arranged. In the word line direction, the adjacent pillar-shaped gate electrodes are electrically connected to each other, and, in a first bit line direction, the adjacent pillar-shaped gate electrodes are electrically insulated from each other.

### CROSS-REFERENCE TO RELATED APPLICATION

This application is based upon and claims the benefit of priority from Japanese Patent Application No. 2012-142526, filed Jun. 25, 2012; the entire contents of which are incorporated herein by reference.

### FIELD

Embodiments described herein relates generally to a semiconductor memory device and its manufacturing method.

### BACKGROUND

In recent years, Floating Body Cell (FBC) volatile memory has been developed for use as a memory element. An n-type MOSFET (MOS Field Effect Transistor) formed with SOI (Silicon On Insulator) is utilized so that holes generated by ion impact at a drain end of the MOSFET are enclosed in the p-type region of a channel lower portion.

However, for the FBC using FINFET (Fin Field Effect Transistor), electrodes corresponding to the back gate electrodes cannot be formed, and the FBC is prone to degradation in data retention characteristics, which is undesirable.

### DESCRIPTION OF THE DRAWINGS

FIGS. 1A to 1C are diagrams illustrating a semiconductor memory device according to an embodiment. FIG. 1A is a plan view. FIG. 1B is a cross-sectional view taken across A-A′ in FIG. 1A. FIG. 1C is a cross-sectional view taken across B-B′ in FIG. 1A.

FIG. 2 is a plan view illustrating a memory-cell divided structure of the semiconductor memory device according to the embodiment.

FIGS. 3A and 3B are plan views illustrating an upper wiring structure in the semiconductor memory device according to another embodiment. FIG. 3A shows a first upper wiring layer and FIG. 3B shows a second upper wiring layer.

FIGS. 3C and 3D are side cross-sectional views of FIG. 3B. FIG. 3C is a cross-sectional view across line 3C-3C and FIG. 3D is a cross-sectional view across line 3D-3D.

FIG. 3E is a plan view showing a third upper wiring layer.

FIGS. 3F and 3G are side cross-sectional views of FIG. 3E. FIG. 3F is a cross-sectional view across line 3F-3F and FIG. 3G is a cross-sectional view across line 3G-3G.

FIGS. 4A to 11C are diagrams illustrating a manufacturing method of the semiconductor memory device according to the embodiments.

FIG. 4A is a plan view, FIG. 4B is a cross-sectional view taken across A-A′ in FIG. 4A, and FIG. 4C is a cross-sectional view taken across B-B′ in FIG. 4A.

FIG. 5A is a plan view, FIG. 5B is a cross-sectional view taken across A-A′ in FIG. 5A, and FIG. 5C is a cross-sectional view taken across B-B′ in FIG. 5A.

FIG. 6A is a plan view, FIG. 6B is a cross-sectional view taken across A-A′ in FIG. 6A, and FIG. 6C is a cross-sectional view taken across B-B′ in FIG. 6A.

FIG. 7A is a plan view, FIG. 7B is a cross-sectional view taken across A-A′ in FIG. 7A, and FIG. 7C is a cross-sectional view taken across B-B′ in FIG. 7A.

FIG. 8A is a plan view, FIG. 8B is a cross-sectional view taken across A-A′ in FIG. 8A, and FIG. 8C is a cross-sectional view taken across B-B′ in FIG. 8A.

FIG. 9A is a plan view, FIG. 9B is a cross-sectional view taken across A-A′ in FIG. 9A, and FIG. 9C is a cross-sectional view taken across B-B′ in FIG. 9A.

FIG. 10A is a plan view, FIG. 10B is a cross-sectional view taken across A-A′ in FIG. 10A, and FIG. 100 is a cross-sectional view taken across B-B′ in FIG. 10A.

FIG. 11A is a plan view, FIG. 11B is a cross-sectional view taken across A-A′ in FIG. 11A, and FIG. 11C is a cross-sectional view taken across B-B′ in FIG. 11A.

### DETAILED DESCRIPTION

Embodiments provide a semiconductor memory device with a high resistance to degradation of data retention characteristics, and a manufacturing method thereof.

In general, the embodiments will be explained with reference to the drawings.

The semiconductor memory device according to one embodiment has a semiconductor laminated film having a semiconductor substrate, an embedded insulating film and an SOT layer laminated to each other. On the embedded insulating film, multiple pillar-shaped gate electrodes embedded in the SOI layer are arranged. On the SOI layer, a pillar-shaped gate insulating film is arranged to surround the side surface of each aforementioned pillar-shaped gate electrode. On the SOT layer, multiple first bit lines are arranged. On the pillar-shaped gate electrodes, multiple word lines are arranged. In the word line direction, the adjacent pillar-shaped gate electrodes are electrically connected to each other, and, in a first bit line direction, the adjacent pillar-shaped gate electrodes are electrically insulated from each other.

### Embodiment

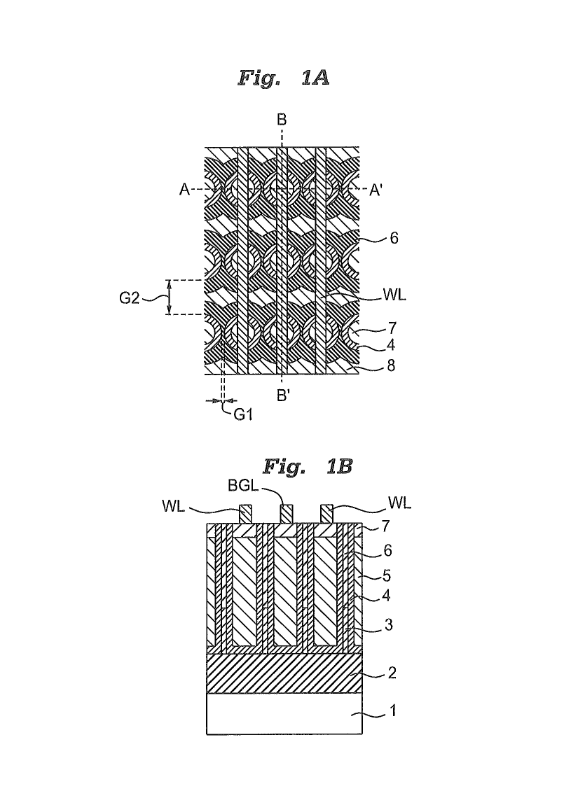

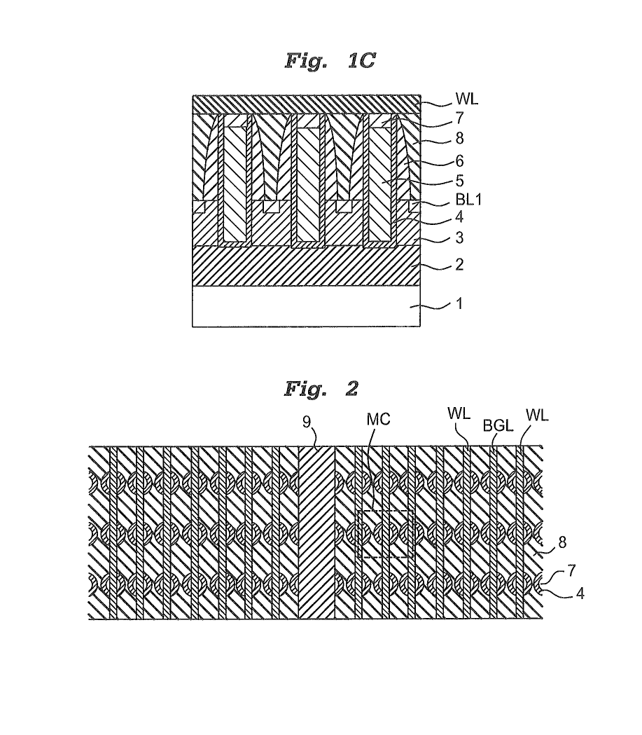

FIGS. 1A to 1C are diagrams illustrating the semiconductor memory device according to the embodiment. FIG. 1A is a plan view. FIG. 1B is a cross-sectional view taken across A-A′ in FIG. 1A. FIG. 1C is a cross-sectional view taken across B-B′ in FIG. 1A.

On a semiconductor substrate 1, an embedded insulating film 2 and an SOI (Silicon On Insulator) layer having a diffusion layer are arranged. Here, the laminated films of the semiconductor substrate 1, the embedded insulating film 2 and the SOI layer 3 are called semiconductor laminated films. The SOI layer 3 is a silicon film arranged on the embedded insulating film 2. The SOI layer 3 has multiple p-type silicon regions and n-type silicon regions arranged. The n-type silicon regions extend in the direction of a first bit line BL1, and they are separated from each other by the p-type silicon regions and a pillar-shaped gate insulating film 4. The p-type silicon regions are arranged as each of them is sandwiched between the n-type silicon region and a pillar-shaped gate electrode 5.

On the n-type silicon regions of the SOI layer 3, multiple first bit lines BL1 extending in the direction of the first bit lines BLT are arranged. For example, the first bit lines BL1 are made of NiSi or other silicide film.

On the embedded insulating film 2, in a direction nearly perpendicular to the semiconductor substrate 1, multiple pillar-shaped gate electrodes 5 (having an optional silicide film 7 formed on the pillar-shaped gate electrodes 5) and pillar-shaped gate insulating films 4 are formed in an SOI layer 3 to form the pillar-shaped gates. Here, the pillar-shaped gate insulating film 4 is arranged between the pillar-shaped gate electrode 5 and the SOI layer 3 to cover the pillar-shaped gate electrode 5. The pillar-shaped gate electrodes 5 are arranged in a matrix. For example, they are arranged almost equidistantly in the word line WL direction and the direction of the first bit lines BL1, respectively. The pillar-shaped gate insulating film 4 may be made of a silicon oxide film, and the pillar-shaped gate electrode 5 may be made of a polysilicon layer. The pillar-shaped gate electrodes 5 adjacent to each other along the word line WL direction are electrically connected with each other, and the pillar-shaped gate electrodes 5 adjacent along the direction of the first bit lines BL1 are electrically insulated from each other. As an example, the first pillar-shaped gate insulating films 4 and pillar-shaped gate electrode 5 may have a cylinder shape. Also, the pillar-shaped gate insulating film 4 and the pillar-shaped gate electrodes 5 may be embedded in the embedded insulating film 2. As shown in FIGS. 1A to 1C, a silicide film 7 is provided on the pillar-shaped gate electrode 5. However, in other embodiments, the silicide film 7 need not be provided on the pillar-shaped gate electrode 5.

On the SOI layer 3, a gate side wall insulating film 6 is arranged to cover the side surface of the pillar-shaped gate insulating film 4. For example, the gate side wall insulating film 6 may be made of a silicon oxide film. The gate side wall insulating film 6 may have a round shape with the center of the pillar-shaped gate electrode 5 at the center of the circle in the plan view. The gate side wall insulating film 6 is arranged so that it is embedded on the SOI layer 3 between the pillar-shaped gate insulating films 4 adjacent to each other in the direction of the first bit lines BL1. The gate side wall insulating film 6 covers a portion of the SOI layer 3 between the pillar-shaped gate insulating films 4 adjacent to each other in the word line WL direction.

Here, the distances between the adjacent gate side wall insulating films 6 are defined as follows: in the plan view of the pillar-shaped gate electrodes 5, on a straight line passing through the centers of the nearly round shapes and along the direction of the first bit lines BL1, a distance between the outer surfaces of the adjacent pillar-shaped gate insulating films 4 is G1, and, in the plan view of the pillar-shaped gate electrodes 5, on a straight line passing through the centers of the nearly round shapes and along the word line WL direction, a distance between the outer surfaces of the adjacent pillar-shaped gate insulating films 4 is G2. In this case, the maximum film thickness d (distance defined by G1 or G2) of the gate side wall insulating films 6 is defined as formula (1) below.

G1/2<d<G2/2 (1)

When the maximum film thickness d of the gate side wall insulating films 6 meets the condition defined by formula (1), in the direction of the first bit lines BL1, as shown in FIG. 1B, the gate side wall insulating film 6 is arranged between the pillar-shaped gate insulating films 4 on the SOI layer 3. In the word line direction, as shown in FIG. 10, there are portions free of the gate side wall insulating film 6 between the pillar-shaped gate insulating films 4 on the SOI layer 3. As a result, the first bit lines BL1 are formed as a self-aligned structure as a silicide film in the regions where the SOI layer 3 is exposed (extending directionally into the paper as shown in FIG. 10).

The first bit lines BL1 are arranged on the surface of the SOI layer 3 where the SOI layer 3 is not covered by the gate side wall insulating film 6. The first bit lines BL1 are a silicide film, NiSi film or CoSi film. Also, the first bit lines BL1 may be made of polysilicon layer.

On the first bit lines BL1, an interlayer insulating film 8 is arranged to cover the side surface of the gate side wall insulating film 6. The interlayer insulating film 8 is made of, for example, silicon oxide film.

On the pillar-shaped gate electrode 5, a first upper wiring layer (shown as word lines WL and back gate lines BGL) is arranged in the direction almost perpendicular to the direction of the first bit lines BL1. On the first upper wiring layer, the wires as the word lines WL and the back gate lines BGL are arranged alternately. On the pillar-shaped gate electrodes 5 in the word line WL direction, the first upper wiring layer is shared.

FIG. 2 is a plan view illustrating a memory-cell divided structure of the semiconductor memory device according to the first embodiment. As shown in FIG. 2, the first bit lines BL1, which are not shown in FIG. 2 as the first bit lines BL1 are hidden by the interlayer insulating film 8 (see FIG. 1C), are segmented with a prescribed interval corresponding to each of a prescribed number of memory cells MC (one is shown in FIG. 2), respectively. The divided memory cell structure is called memory-cell divided structure. In this embodiment, multiple memory-cell divided structures are arranged.

For example, the first bit lines BL1 are segmented corresponding to about 10,000 memory cells in the direction of the first bit lines BL1, respectively, which are disposed generally in an perpendicular direction relative to the direction of the word lines WL and the back gate lines BGL (in the left-right direction of the page). Dividing of the first bit lines BL1 in the memory-cell divided structure may be carried out by, for example, a silicon insulating film adopted as a dividing insulating film 9. The dividing insulating film 9 is embedded in the SOI layer 3 and the interlayer insulating film 8 so that it is in contact with the embedded insulating film 2.

As a result, it is possible to suppress the OFF current leaking from the first bit line BL1 via the p-type silicon region to the adjacent first bit line BL1 to a prescribed current value, and it is possible to increase the ratio of the ON current to OFF current of the memory cells. That is, it is possible to suppress the error in the read operation and increase in the power consumption caused by the OFF current. Here, the ON current refers to the current flowing in the channel when a voltage higher than the threshold voltage is applied on the gate electrode of the memory cell, and the OFF current refers to the current flowing in the channel when a voltage lower than the threshold voltage is applied on the gate electrode of the memory cell. As an example of the sub-threshold characteristics of the MOSFET, suppose the OFF current flowing in one memory cell is 1×10⁻¹⁰ A, and the ON current is 1×10⁻³ A. In this case, when about 10,000 memory cells are set side by side, the total leak OFF current from all of the memory cells is about 1×10⁻⁷ A. Thus, the ON current and the OFF current are different from each other by about three orders of magnitude. As a result, it is possible to suppress errors in the read operation caused by the OFF current.

With the memory-cell divided structure, due to dividing, the side surface of the p-type silicon region of the SOI layer 3 as the channel does not become the end of the memory-cell divided structure, and the region of the pillar-shaped gate electrode 5 or the pillar-shaped gate insulating film 4 becomes the end of the memory cell structure. As a result, it is possible to suppress the OFF current from the p-type silicon region that would take place when the p-type silicon region of the SOI layer 3 becomes the end of the memory-cell divided structure.

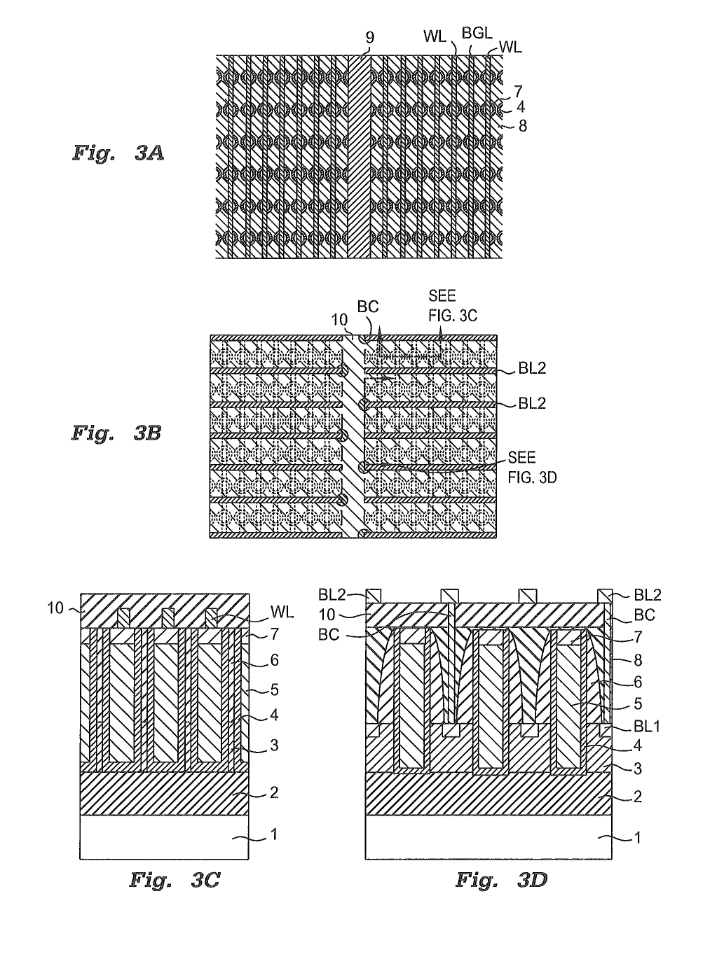

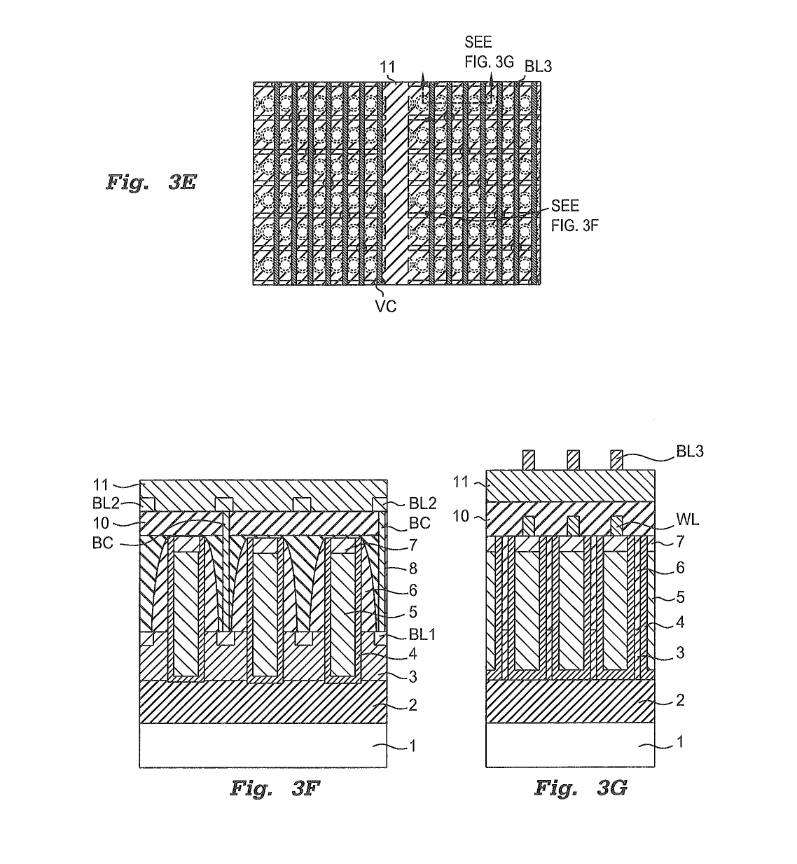

FIGS. 3A, 3B and 3E are plan views illustrating the upper wiring structure in the semiconductor memory device according to another embodiment. FIG. 3A shows the first upper wiring layer, FIG. 3B shows a second upper wiring layer, and FIG. 3G shows a third upper wiring layer. FIGS. 3C and 3D are side cross-sectional views of FIG. 3B. FIG. 3C is a cross-sectional view across line 3C-3C of FIG. 3B and FIG. 3D is a cross-sectional view across line 3D-3D of FIG. 3B. FIGS. 3F and 3G are side cross-sectional views of FIG. 3E. FIG. 3F is a cross-sectional view across line 3F-3F of FIG. 3E and FIG. 3G is a cross-sectional view across line 3G-3G of FIG. 3E.

As shown in FIG. 3A, the first upper wiring layer, the word lines WL and the back gate lines BGL are arranged to extend in the direction of the word lines on the pillar-shaped gate electrodes 5, which are not shown in FIG. 3A as the pillar-shaped gate electrodes are hidden by the silicide film 7 (see FIG. 10). The first upper wiring layer has the word lines WL and the back gate lines BGL arranged alternately in the direction of the first bit lines BL1.

As shown in FIG. 3B, a bit line contact BC is arranged on the end of the first bit line BL1 (not shown in FIG. 3B as first bit line BL1 is hidden by an inter-wiring insulating film 10 on the interlayer insulating film 8) in the memory-cell divided structure. The bit line contact BC connects first bit line BL1 (in a lower layer of the semiconductor memory device) to second bit line BL2 (in an upper layer of the semiconductor memory device) as shown in FIG. 3D. The interlayer insulating film 8 may comprise the dividing insulating film 9 (shown in FIG. 3A). As a result, it is possible to form the bit line contact without contact with the first upper wiring layer extending in the direction almost perpendicular to the direction of the first bit lines BL1 on the memory cells.

On the bit line contact arranged on the end of the memory-cell divided structure, second bit lines BL2 are arranged as the second upper wiring layer. The second bit lines BL2 extend in the direction almost perpendicular to the word line direction on the bit line contact arranged on the end of the memory-cell divided structure. The second bit lines BL2 are the bit lines of the cell block units (CBBL), and they are arranged corresponding to the first bit lines BL1, respectively, in the memory-cell divided structure, and they are not shared with the other memory-cell divided structure.

As shown in FIG. 3E, third bit lines BL3 are arranged as the third upper wiring layer extending in the word line direction and in contact with the second bit lines BL2 by via contacts. The via contacts that connect the third bit lines BL3 and the second bit lines BL2 are arranged on the adjacent second bit lines BL2 shifted from each other by one memory cell in the direction of the second bit lines BL2.

As a result, the wiring structure of the semiconductor memory device according to the embodiment is formed.

In the following, the manufacturing method of a nonvolatile semiconductor memory device according to the embodiments will be explained.

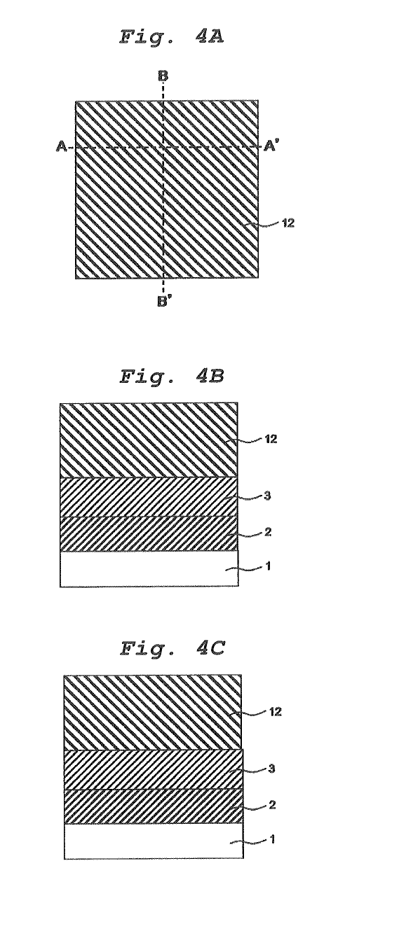

FIG. 4A to FIG. 11C are cross-sectional views illustrating the manufacturing method of the semiconductor memory device according to one embodiment. FIG. 4A is a plan view, FIG. 4B is a cross-sectional view taken across A-A′ in FIG. 4A, and FIG. 40 is a cross-sectional view taken across B-B′ in FIG. 4A.

As shown in FIGS. 4A to 4C, a SiN film is formed as a hard mask 12 on the semiconductor laminated film. The semiconductor laminated film is a laminated film formed by layering an embedded insulating film 2 and an SOI layer 3 on a semiconductor substrate 1. For example, the SOI layer 3 is a p-type silicon film.

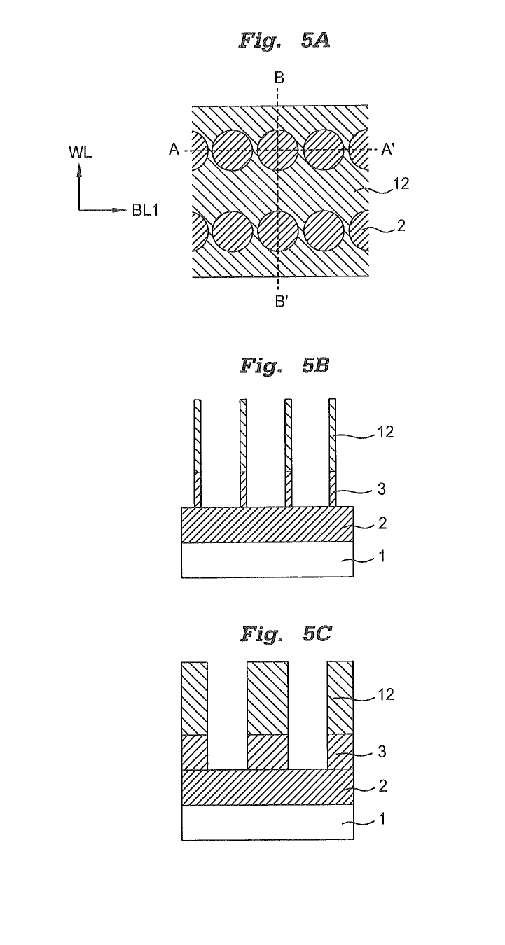

Then, as shown in FIGS. 5A to 5C, the photolithographic method is utilized to form and process a resist film on the hard mask 12. Then, with the processed resist film as a mask, the hard mask 12 is etched by RIE. Then, using the hard mask 12 as a mask, the SOI layer 3 is etched to form blind holes (trenches). In this case, one may also adopt a method in which a portion of the upper portion of the embedded insulating film 2 may be etched.

Here, the distance between the adjacent blind holes is defined as follows: on a straight line passing through the centers of the nearly round shapes of the blind holes in the plan view (where the pillar-shaped gate electrodes 5 will be formed-see FIG. 1B), the distances between the outer surfaces of the adjacent blind holes in the direction of the first bit lines BL1 or along the direction of the word lines is different. In this case, the distance between the adjacent blind holes along the word line direction is greater than the distance between the adjacent blind holes along the direction of the first bit lines BL1.

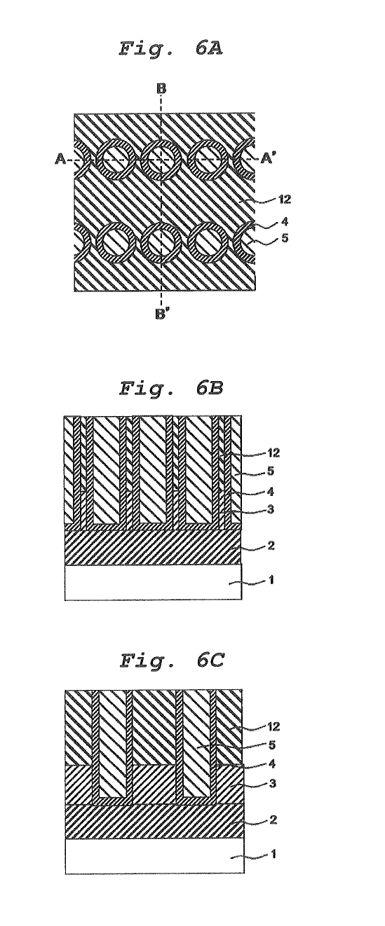

Then, as shown in FIGS. 6A to 6C, on the inner surface of each blind hole, a silicon oxide film is formed as the pillar-shaped gate insulating film 4. Then, on the side surface of the pillar-shaped gate insulating film 4 in the blind hole, an n-type silicon layer is embedded as the pillar-shaped gate electrode 5. Then, the silicon oxide film and a polysilicon layer formed on the hard mask 12 are removed by CMP processing.

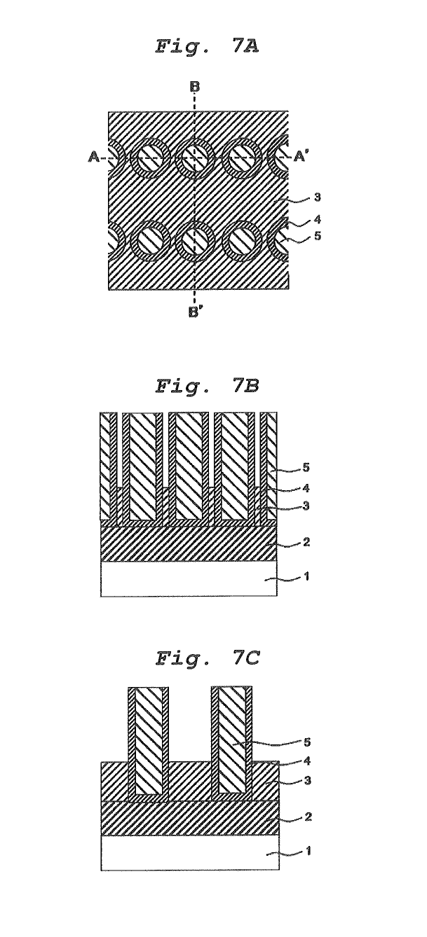

Then, as shown in FIGS. 7A to 7C, the SiN film adopted as the hard mask 12 on the SOI layer 3 is selectively etched by a mixture solution of, for example, phosphoric acid and water.

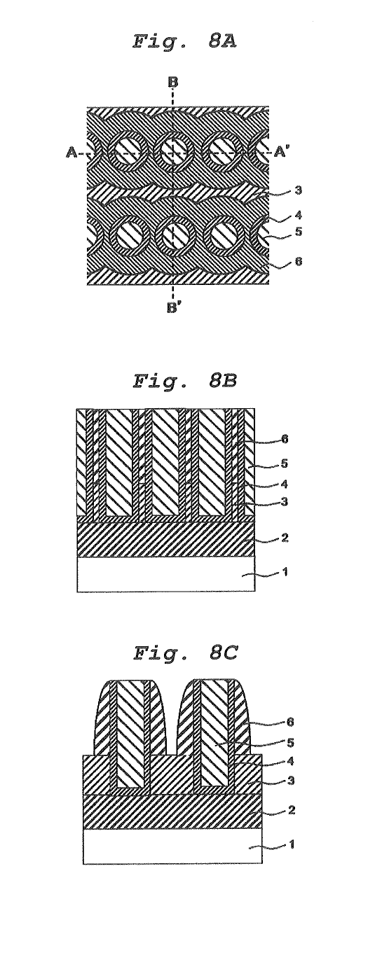

Then, as shown in FIGS. 8A to 8C, a gate side wall insulating film 6 is formed to cover the side surface of the pillar-shaped gate insulating films 4 on the SOI layer 3. The gate side wall insulating film 6 is embedded on the SOI layer 3 between the pillar-shaped gate insulating films 4 adjacent to each other in the direction of the first bit lines BL1, and the gate side wall insulating film 6 is formed so that a portion of the SOI layer 3 is exposed between the pillar-shaped gate insulating films 4 adjacent to each other in the word line direction. That is, the gate side wall insulating films 6 are formed so that the maximum film thickness d of the gate side wall insulating films 6 meets the relationship represented by formula (I) listed above.

Then, ion implanting is carried out with an n-type dopant using the gate side wall insulating films 6 as a mask. The regions where the SOI layer 3 is exposed become an n-type silicon region.

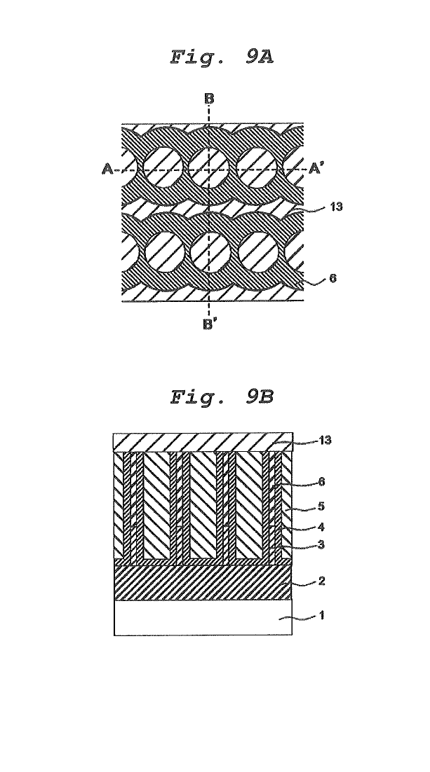

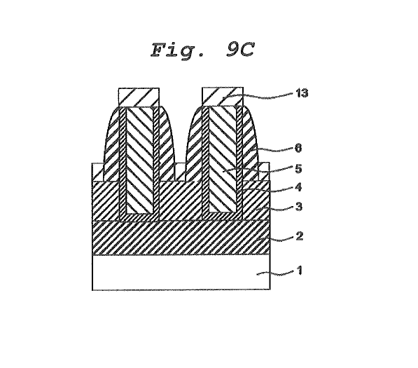

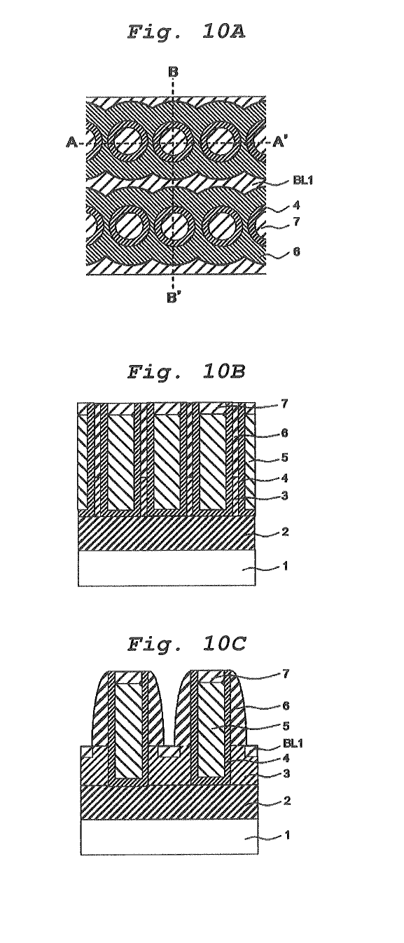

Then, as shown in FIGS. 9A to 9C, on the n-type silicon region of the exposed SOI layer 3, a metal film 13, for example, a Ni film is formed. In this case, the metal film 13 may also be formed on the pillar-shaped gate electrodes 5.

Then, as shown in FIGS. 10A to 10C, heat treatment is carried out so that the Ni atoms contained in the metal film 13 diffuse to the polysilicon layer of the n-type silicon regions of the SOI layer 3. As a result, a silicide film, for example, a NiSi film, is formed on the surface of the n-type silicon regions of the exposed SOI layer 3. The n-type NiSi film arranged as the SOI layer 3 functions as the first bit lines BL1. In the manufacturing method of the semiconductor memory device according to the embodiment, a silicide film with a low resistance is formed as the first bit lines BL1 in a self aligned configuration in the silicide formation process. After that, the excess metal film 13 is removed. Also, when the metal film 13 is formed on the pillar-shaped gate electrodes 5 by heat treatment, the Ni atoms contained in the metal film 13 diffuse to the polysilicon layer on the pillar-shaped gate electrodes 5, forming a silicide film 7 on the pillar-shaped gate electrodes 5.

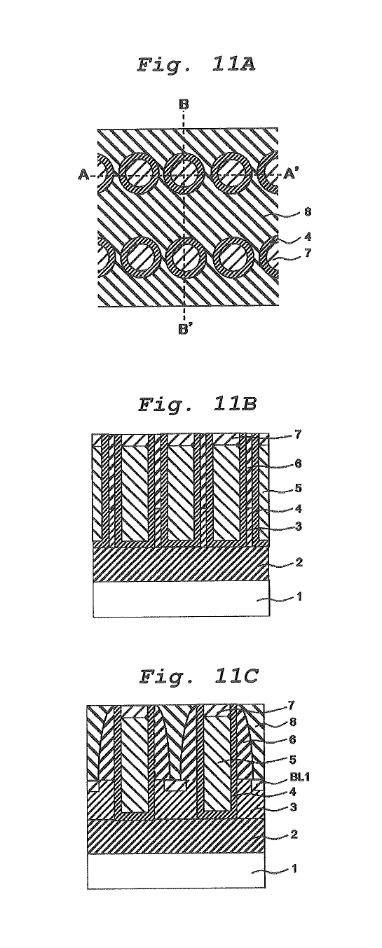

Then, as shown in FIGS. 11A to 11C, the interlayer insulating film 8 is formed on the side surface of the SOI layer 3 and the gate side wall insulating film 6, and CMP treatment is then performed to flatten the interlayer insulating film 8.

Then, as shown in FIG. 2, a plurality of memory cells are segmented in the word line direction to form a memory-cell divided structure. For example, while 10,000 memory cells are not shown in FIG. 2 (due to space restrictions and for clarity), for each 10,000 memory cells in the first bit line BL1 direction (perpendicular to the word line direction) are separated in the memory-cell divided structure. Segmenting the memory cells is performed by etching the pillar-shaped gate electrodes 5, the pillar-shaped gate insulating films 4, the gate side wall insulating films 6 and the SOI layer 3.

Then, as shown in FIG. 3A, electrode films are formed on the pillar-shaped gate electrodes 5, and, by processing in a direction almost perpendicular to the direction of first bit lines BL1, the first upper wiring layer is formed. Here, as the bit line contact is formed on the first bit lines BL1, the first upper wiring layer is not formed on the pillar-shaped gate electrode 5 at each end of the memory-cell divided structures, respectively.

Then, a silicon oxide film is formed as an inter-wiring insulating film 10 on the interlayer insulating film 8 to cover the first upper wiring layer (see FIGS. 3B to 3D).

Then, the inter-wiring insulating film 10 and the interlayer insulating film 8 are etched to form contact holes. Asa result, the first bit line BL1 at the end of the memory-cell divided structure is exposed. For the exposed first bit line BL1, the inter-wiring insulating film 10 and the interlayer insulating film 8 are etched at the first bit line BL1 exposed on one end so that adjacent first bit line BL1 is exposed on the other end.

Then, the bit line contact BC is formed on the exposed first bit line BL1 in the contact hole (see FIGS. 3B to 3D).

Then, as shown in FIG. 3B, a wiring extending in a direction parallel to the first bit lines BL1 is formed on the bit line contact, and, along the memory-cell divided structure, wiring is processed to form the second bit lines BL2 as the second upper wiring layer. Consequently, the memory-cell divided structure is arranged for each of the first bit lines BL1, and it is not shared with the other memory-cell divided structure.

Then, on the inter-wiring insulating film 10, a silicon oxide film is formed as the inter-wiring insulating film 11 to cover the second bit lines BL2 (see FIGS. 3E-3G).

Then, the inter-wiring insulating film 11 is processed to form the via holes so as to expose the second bit lines BL2. The via holes are formed by shifting for one pillar-shaped gate electrode 5 in the direction of the second bit lines BL2 at the adjacent second bit lines BL2 just as the contacts connecting the second bit lines BL2 and the third bit lines BL3 as shown in FIG. 3E.

Then, as shown in FIG. 3E, the third bit lines BL3 are formed as the third upper wiring layer parallel with the first upper wiring layer. The third bit lines BL3 are connected with the second bit lines BL2 by the via contacts VC.

In operation, the upper wiring structure of the semiconductor memory device according to the embodiments is formed.

In the following, the operation of the semiconductor memory device according to the embodiment will be explained with reference to the drawings.

### (Write Operation of Data)

Portions of the first upper wiring layer are arranged on the pillar-shaped gate electrodes 5 have the portions working as word lines and the portions working as the back gate lines alternately provided. Here, the word lines are the wiring for applying voltage on the pillar-shaped gate electrodes 5, and the back gate lines are the wiring for applying a negative voltage on the pillar-shaped gate electrodes 5 for accumulating the holes generated by impact ionization.

In addition, for the first bit lines BL1, the second bit lines BL2 and the third bit lines BL3, the bit lines are arranged corresponding to each other in the one-to-one configuration. In the following, in order to facilitate the explanation, the case when the voltage is applied on the first bit lines BL1 will be explained.

Supposing the voltage applied on the first bit lines BL1 and the word lines as the ground voltage, for example, is 0 V. Also, a negative voltage of Vbg (for example, −1.0 V) is applied to the entire back gate lines. Then, a positive voltage (for example, 0.8 V) is applied as a voltage Vg higher than the threshold voltage at the pillar-shaped gates is applied on the word lines corresponding to the memory cells for data write operation. Then, a positive voltage (for example, 1.2 V) is applied as the write voltage VD on one of the first bit lines BL1 adjacent to the memory cell.

As a result, a potential difference is generated between the first bit lines BL1 adjacent to the memory cell, and the electrons flowing from the source side are impact ionized at the drain end. The holes generated at the drain end are pulled to the pillar-shaped gate electrode 5 that works as an adjacent back gate and has a negative voltage applied on it. That is, the holes are accumulated in the p-type silicon region as the SOI layer 3 near the pillar-shaped gate insulating film 4 of the back gate. Consequently, the threshold voltage of the pillar-shaped gate increases, and the data are written. In this case, in the SOI layer 3, the holes are accumulated near the two back gate insulating films adjacent to the word line. That is, when data are written in one memory, holes are accumulated simultaneously in the two regions of the SOI layer 3.

As the write voltage of, for example, 1.2 V, and 0 V as the ground voltage are alternately applied on the first bit lines BL1, a potential difference takes place between the adjacent first bit lines BL1, so that the data can be written en bloc in the memory cells corresponding to the same word line.

In addition, when data are to be written in only one memory cell, it is necessary to ensure equal potential without potential difference other than between the first bit lines BL1 adjacent to the memory cell for data write. For example, the voltages applied on the first bit lines BL1 on one side of the memory cell for data write are all at 1.2 V, while the voltages applied on the first bit lines BL1 on the other side are all at 0 V.

### (Read Operation of Data)

Supposing the voltage applied on the first bit lines BL1 and the word line as the ground voltage is, for example, 0 V. In addition, a negative voltage (for example, −1.0 V) is applied as Vbg on all of the back gate lines. Then, a positive voltage (for example, 0.8 V) as voltage Vg higher than the threshold voltage (without data write) at the pillar-shaped gates is applied on the word line corresponding to the memory cell for data read. Then, a positive voltage (for example, 0.3 V) is applied as the read voltage VD on one of the first bit lines BL1 adjacent to the memory cell. The read voltage VD is lower than the write voltage, and a voltage that does not cause impact ionization is used. It is not a necessity to ensure equal potential (free of potential difference) except between the first bit lines BL1 adjacent to the memory cell for data read. For example, the voltages applied on the first bit lines BL1 on one side of the memory cell for data read are all at 1.2 V, and the potentials applied on the first bit lines BL1 on the other side are all at 0 V.

When data are written in the memory cell for data read operation, the threshold voltage of the memory cell increases, so that it is possible to read whether data are written by determining whether a current flows when a voltage lower than the threshold voltage is applied on the word line.

### (Deletion Operation of the Data)

Supposing the voltage applied on the first bit lines BL1 and the word line as the ground voltage is at, for example, 0V. Also, a negative voltage (for example, −1.0 V) is applied as Vbg to the entire back gate lines. Then, 0 V as the ground voltage is applied on the back gate lines adjacent to the memory cell for deletion operation. Then, a positive voltage (for example, 0.8 V) as the voltage Vg higher than the threshold voltage at the pillar-shaped gate is applied on the word line corresponding to the memory cell for data deletion. Then, a positive voltage (for example, 0.3V) is applied as the deletion voltage VD on one of the first bit lines BL1 adjacent to the memory cell. The deletion voltage VD is lower than the write voltage, and it is a voltage without causing impact ionization.

As the negative voltage applied on the back gate lines is not applied, the holes accumulated in the SOI layer 3, that is, the p-type silicon region, near the pillar-shaped gate insulating film 4 in the back gate flow to the adjacent first bit lines BL1 with a lower potential. As a result, the data are deleted.

As explained above, according to the embodiments, the first upper wiring layer that can control the voltages applied on the pillar-shaped gate electrodes 5, independently, and respectively, is arranged. As a result, the first upper wiring layer can have the function of the back gate lines independent of, and in addition to, the word lines. Consequently, the hole accumulation can be kept in the SOI layer 3 near the back gate, so that it is possible to provide a semiconductor memory device free of degradation in the data retention characteristics.

In addition, according to the embodiment, the first bit lines BL1 are segmented at a prescribed interval, and they are divided corresponding to each group of a prescribed number of memory cells to form multiple memory-cell divided structures. As a result, it is possible to suppress the OFF current leaking from the first bit line BL1 via the p-type silicon region to the adjacent first bit lines BL1 to a prescribed current value, and it is possible to increase the ratio of the ON current to the OFF current of the memory cell. That is, it is possible to suppress the error in the read operation and an increase in power consumption caused by the OFF current.

In addition, according to the manufacturing method of the semiconductor memory device according to the embodiments, the silicide film as the first bit lines BL1 is formed using the self alignment method, that is, a so-called self-aligned silicide process, instead of a photolithographic method. Consequently, it is possible to form the first bit lines BL1 in a simple manufacturing operation, which reduces the manufacturing cost.

However, the present disclosure is not limited to the embodiment. As long as the gist of the present disclosure is observed, various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a laminated film formed above a substrate, the laminated film comprising an insulating film and an SOI layer formed on the insulating film;
a plurality of pillar-shaped gate electrodes partly embedded in the SOT layer;
a pillar-shaped gate insulating film surrounding a side surface of each of the pillar-shaped gate electrodes;
a plurality of bit lines provided at an upper portion of the SOI layer and extending in a first direction; and
an upper wiring layer provided on the pillar-shaped gate electrodes and including word lines and back gate lines that are arranged alternately in second direction perpendicular to the first direction,
wherein adjacent pillar-shaped gate electrodes are electrically connected to each other along the second direction, and adjacent pillar-shaped gate electrodes are electrically insulated from each other along the first direction.

2. The semiconductor memory device according to claim 1, further comprising:
a gate side wall insulating film that covers a side surface of the pillar-shaped gate insulating film.

3. The semiconductor memory device according to claim 2, wherein the gate side wall insulating film is embedded between pillar-shaped gate insulating films above the SOI layer.

4. The semiconductor memory device according to claim 3, wherein the bit lines are arranged on a surface of the SOI layer in regions where the gate side wall insulating film does not cover the SOI layer.

5. The semiconductor memory device according to claim 4, wherein the bit lines comprise a silicide film.

6. The semiconductor memory device according to claim 1, further comprising:
a dividing insulating film separating a first group of the bit lines from a second group of the bit lines.

7. A semiconductor memory device comprising:
a substrate;
an insulating film formed above the substrate;
an SOI layer formed on the insulating film;
a plurality of pillar-shaped gate electrodes partly disposed in trenches formed in the SOI layer on the insulating film;
a pillar-shaped gate insulating film surrounding a side surface of each of the pillar-shaped gate electrodes adjacent the SOI layer;
a plurality of first bit lines provided at an upper portion of the SOI layer and extending in a first direction; and
an upper wiring layer provided on the pillar-shaped gate electrodes and including word lines and back gate lines that are arranged alternately in a second direction perpendicular to the first direction;
a plurality of second bit lines provided above the upper wiring layer in the first direction,
wherein adjacent pillar-shaped gate electrodes are electrically connected to each other along a second direction, and adjacent pillar-shaped gate electrodes are electrically insulated from each other along the first direction.

8. The semiconductor memory device according to claim 7, further comprising:
a dividing insulating film separating a first group of the first bit lines from a second group of the first bit lines.

9. The semiconductor memory device according to claim 7, further comprising:
a plurality of contacts each connecting one of the first bit lines to one of the second bit lines.

10. The semiconductor memory device according to claim 9, further comprising:
a plurality of third bit lines provided above the second bit lines and extending along the second direction, each of the third bit lines being connected to one of the second bit lines.

11. The semiconductor memory device according to claim 7, wherein
when data are written in the memory cells of the semiconductor memory device, a voltage higher than a threshold voltage of the pillar-shaped gate electrode is applied on a word line in each of the memory cells to perform a write operation, and a negative voltage is applied on the adjacent back gate line, and different voltages are applied on the first bit lines adjacent to each other in the second direction in the memory cells.

12. The semiconductor memory device according to claim 7, wherein
when data are read from the memory cells of the semiconductor memory device, a voltage higher than a threshold voltage of the pillar-shaped gate electrode is applied on a word line in each of the memory cells to perform the read operation, a negative voltage is applied on an adjacent back gate line, and different voltages are applied on the first bit lines adjacent to each other in the second direction in the memory cells.

13. The semiconductor memory device according to claim 7, wherein
when data deletion is performed for the memory cells of the semiconductor memory device, a voltage higher than a threshold voltage of the pillar-shaped gate electrode is applied on a word line in the memory cell to perform the deletion operation, a ground voltage is applied on an adjacent word line, and different voltages are applied on first bit lines adjacent to each other in the word line direction in the memory cells.

14. A method of manufacturing a semiconductor memory device, the method comprising:
forming a mask layer on a semiconductor laminated film including a semiconductor substrate, an insulating film on the semiconductor substrate, and an SOI layer on the insulating film;
forming multiple holes through the mask layer so as to expose the SOI layer, wherein a distance between adjacent holes along a first direction is shorter than along a second direction that is perpendicular to the first direction;
forming a pillar-shaped gate insulating film on an inner surface of each of the multiple holes;
forming multiple pillar-shaped gate electrodes on the pillar-shaped gate insulating film within the holes;
removing the mask layer to expose upper portions of the pillar-shaped gate insulating film;
forming a gate side wall insulating film to cover the exposed side surfaces of the pillar-shaped gate insulating film;
forming bit lines that extend in the first direction; and
forming an upper wiring layer including word lines and back gate lines that extend in the second direction.

15. The method of claim 14, wherein the word lines and the back gate lines are alternately arranged in the upper wiring layer along the second direction.

16. The method of claim 15, wherein the bit lines include first bit lines formed at an upper portion of the SOI layer and second bit lines formed above the upper wiring layer.

17. The method of claim 16, further comprising forming additional bit lines that extend in the first direction above the second bit lines.

18. The method of claim 16, wherein the first bit lines are formed from a metal film that is deposited on top of the SOI layer that is not covered by the gate side wall insulating film.

19. The method of claim 14, wherein said forming the bit lines includes:
implanting n-type dopants into a surface of the SOI layer that is not covered by the gate side wall insulating film;
depositing a metal film onto the surface of the SOI layer; and
heating the SOI layer and the metal film to cause the dopants implanted in the SOI layer to diffuse into the metal film and form a silicide layer.

20. The method of claim 19, further comprising:
forming an insulating film above the silicide layer to cover the silicide layer and exposed side surfaces of the gate side wall insulating film.
